(19) United States
(12) Patent Application Publication
(10) Pub. No.: US 2013/0014516 A1
(43) Pub. Date: Jan. 17, 2013

(54) THERMOELECTRIC MODULE

(71) Applicants: Ju Hwan Yang, Gyeonggi-do (KR); Dong Hyeok Choi, Gyeonggi-do (KR); Sung Ho Lee, Gyeonggi-do (KR); Sung Kwon Wi, Seoul (KR)

(72) Inventors: Ju Hwan Yang, Gyeonggi-do (KR); Dong Hyeok Choi, Gyeonggi-do (KR); Sung Ho Lee, Gyeonggi-do (KR); Sung Kwon Wi, Seoul (KR)

(73) Assignee: Samsung Electro-Mechanics Co., Ltd., Suwon (KR)

(21) Appl. No.: 13/480,022

(22) Filed: May 24, 2012

(30) Foreign Application Priority Data
Jul. 15, 2011 (KR) 10-2011-0070563

(51) Int. Cl. F25B 21/02; H01L 35/30

(52) U.S. Cl. 62/3.7; 136/203

(57) ABSTRACT

Disclosed herein is a thermoelectric module. The thermoelectric module includes a first substrate, a second substrate, a diffusion prevention layer, and a thermoelectric device, wherein each of the first and second substrates is stacked with: a heat radiation layer performing heat generation reaction or heat adsorption reaction when power is applied to the thermoelectric module; an insulating layer formed on one surface of the heat radiation layer and formed in a first square wave pattern having a first protrusion part and a first groove part; and an electrode layer buried into the first groove part formed on a surface of the insulating layer.

### CROSS REFERENCE(S) TO RELATED APPLICATIONS

This application claims the benefit under 35 U.S.C. Section 119 of Korean Patent Application Serial No. 10-2011-0070563, entitled “Thermoelectric Module” filed on Jul. 15, 2011, which is hereby incorporated by reference in its entirety into this application.

### BACKGROUND OF THE INVENTION

1. Technical Field

The present invention relates to a thermoelectric module, and more particularly, to a thermocouple module including a substrate having high heat radiation property.

2. Description of the Related Art

Due to a sudden increase in the use of fossil energy, a problem due to global warming and energy depletion is caused. As a result, an interest in a thermoelectric module has been increased.

The thermoelectric module is a device that is used as a cooling unit by replacing Freon gas, or the like, which is one of the materials causing atmospheric pollution, and is widely used as a small generator using a Seebeck effect.

The thermoelectric module generates heat absorption or cooling by generating a potential difference due to a difference in Fermi energy when current flows to a loop formed by mutually grounding metals using a thermoelectric device as a medium and by transferring energy required to move electrons from one metal surface to the other metal surface by the potential difference.

On the other hand, since heat energy is transferred to the other metal surface as much as energy carried by the electron, heat is generated, which is referred to as a Peltier effect. This is an operation principle of a cooling device by the thermoelectric device.

In this case, a position of heat absorption or heat radiation is determined according to a kind of a semiconductor and a direction in which current flows and a difference in an effect is generated according to a material.

FIG. 1 is a schematic cross-sectional view showing a thermoelectric module having a general structure.

Generally, in a thermoelectric module 10, an N-type thermoelectric device 11 and a P-type thermoelectric device 12 are electrically connected to electrodes 3 and 6. In the thermoelectric module, when DC current is applied, heat absorption is generated from any one of the upper and lower substrates 13 and 14 and heat radiation is generated from the other one thereof. In this case, as described above, the position of heat absorption and heat radiation may be changed by a direction of current.

In this case, the upper and lower substrates 13 and 14 need to have high heat transferability and insulation. Therefore, a method for improving heat transferability and insulation of the upper and lower substrates 13 and 14 has been recently searched.

### SUMMARY OF THE INVENTION

Exemplary embodiments of the present invention relate to a thermoelectric module. An object of the present invention is to provide a unit for increasing heat radiation performance.

According to an exemplary embodiment of the present invention, there is provided a thermoelectric module including a first substrate, a second substrate, a diffusion prevention layer, and a thermoelectric device, wherein each of the first and second substrates is stacked with: a heat radiation layer performing heat generation reaction or heat adsorption reaction when power is applied to the thermoelectric module; an insulating layer formed on one of both surfaces of the heat radiation layer and formed in a first square wave pattern having a first protrusion part and a first groove part; and an electrode layer buried into the first groove part formed on a surface of the insulating layer.

According to another exemplary embodiment of the present invention, there is provided a thermoelectric module including a first substrate, a second substrate, a diffusion prevention layer, and a thermoelectric device, wherein each of the first and second substrates is stacked with: a heat radiation layer performing heat generation reaction or heat adsorption reaction when power is applied to the thermoelectric module and both surfaces of a long side thereof formed to have different patterns; an insulating layer formed on one surface of the heat radiation layer and formed in a first square wave pattern having a first protrusion part and a first groove part; and an electrode layer buried into the first groove part formed on a surface of the insulating layer.

According to another exemplary embodiment of the present invention, there is provided a thermoelectric module including a first substrate, a second substrate, a diffusion prevention layer, and a thermoelectric device, wherein each of the first substrate and the second substrate is stacked with: a heat radiation layer performing heat generation reaction or heat adsorption reaction when power is applied to the thermoelectric module and formed in a first square wave pattern; and an insulating layer formed along a top surface of the heat radiation layer and formed in a second square wave pattern; and an electrode layer formed along a top surface of the insulating layer and formed in a third square wave pattern.

### BRIEF DESCRIPTION OF THE DRAWINGS

FIG. 1 is a diagram showing a general thermoelectric module.

FIG. 2 is a diagram showing the thermoelectric module according to a first exemplary embodiment of the present invention.

FIGS. 3A to 3D are cross-sectional views showing a method for manufacturing an upper substrate of FIG. 2.

FIG. 4 is a diagram showing an upper substrate according to a second exemplary embodiment of the present invention.

FIG. 5 is a diagram showing an upper substrate according to a third exemplary embodiment of the present invention.

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

In describing the present invention, when a detailed description of well-known technology relating to the present invention may unnecessarily make unclear the spirit of the present invention, a detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

Hereinafter, a thermocouple module according to exemplary embodiments of the present invention will be described below with reference to the accompanying drawings.

FIG. 2 is a diagram showing a thermoelectric module according to an exemplary embodiment of the present invention.

As shown in FIG. 2, a thermoelectric module 100 according to the exemplary embodiment of the present invention includes substrates 110 and 120, diffusion prevention layers 132 and 134, and a thermoelectric device 140.

When power is applied to the thermoelectric module 100, the substrates 110 and 120 generate the heat generation reaction or the heat adsorption reaction.

The substrates 110 and 120 according to the exemplary embodiment of the present invention are configured of an upper substrate 110 and a lower substrate 120. In this case, an appearance of a top surface and a bottom surface is formed by the upper substrate 110 and the lower substrate 120.

As described above, each of the upper substrate 110 and the lower substrate 120 may be formed by stacking heat radiation layers 112 and 122, insulating layers 114 and 124, and electrode layers 116 and 126.

In more detail, the upper substrate 110 may be formed by stacking the first heat radiation layer 112, the first insulating layer 114, and the first electrode layer 116 and the lower substrate 120 may be formed by stacking the second heat radiation layer 122, the second insulating layer 124, and the second electrode layer 126.

In this configuration, the first and second heat radiation layers 112 and 122 according to the first exemplary embodiment of the present invention may be formed of the same material and shape, the first and second insulating layers 114 and 124 may also be formed of the same material and shape, and the first and second electrode layers 116 and 126 may also be formed of the same material and shape. Therefore, when the specification of the present invention describes the substrate, the first heat radiation layer 112, the first insulating layer 114, and the first electrode layer 116 on the upper substrate 110 will be simply described. Meanwhile, the description of the second heat radiation layer 122, the second insulating layer 124, and the second electrode layer 126 on the lower substrate 120 overlaps the description of the upper substrate 110 and therefore, the description thereof will be omitted.

The first heat radiation layer 112 may perform the heat generation reaction or the heat adsorption reaction when power is applied to the thermoelectric module 100.

The first heat radiation layer 112 may be formed in a square wave pattern having a first protrusion part 112a and a first groove part 112b. In the exemplary embodiment of the present invention, the case of forming the first heat radiation layer 112 in the square wave pattern increases a total surface area 2.5 times higher than the case of forming the first heat radiation layer in a line shape so as to increase a thermal diffusion coefficient, thereby increasing a thermal diffusion rate.

In this case, the first heat radiation layer 112 may be made of any one of, for example, copper (Cu), aluminum (Al), silver (Ag), or the like, that are a conductive metal.

The first insulating layer 114, which is disposed between the first heat radiation layer 112 and the first electrode layer 116, may be used as an insulator so as not to cause electrical short between the first heat radiation layer 112 and the first electrode layer 116 while serving to radiate heat.

The first insulating layer 114 is disposed along the surface of the first heat radiation layer 112, such that the first insulating layer 114 may be formed in the square wave pattern having the second protrusion part 114a and the second groove part 114b.

Therefore, similar to the first heat radiation layer 112, the total surface area of the first insulating layer 114 is increased, for example, 2.5 times higher than that of the first insulating layer 114 formed in the line shape so as to increase the thermal diffusion coefficient, thereby increasing the thermal diffusion rate.

In this case, the first insulating layer 114 may be made of any one of, for example, alumina, boron nitride, aluminum nitride, silica, and polyimide that are an insulating material having high insulation and heat radiation property.

The first electrode layer 116, which is electrically connected to the thermoelectric device 140, may guide a flow of power when power is applied to the thermoelectric module 100.

The first electrode layer 116 may be buried in the second groove part 114b of the first insulating layer 114 and may be made of any one of, for example, copper (Cu), aluminum (Al), silver (Ag), or the like, that are a conductive metal having high electric conductivity.

A diffusion prevention layer may be configured to include a first diffusion prevention layer 132 that is disposed between a top surface of the thermoelectric device 140 and a bottom surface of the first electrode layer 116 to prevent driving reliability from being degraded due to the diffusion of electrode materials of the first electrode layer 116 to the thermoelectric device 140 and a second diffusion prevention layer 134 that is disposed between a bottom surface of the thermoelectric device 140 and a top surface of the second electrode layer 126 to prevent to prevent driving reliability from being degraded due to the diffusion of electrode materials of the second electrode layer 126 to the thermoelectric device 140.

The thermoelectric device 140 is disposed between the first and second electrode layers 116 and 126, such that when DC current is applied to the first and second electrode layers 116 and 126, heat radiation is generated on the upper substrate 110 and heat adsorption is generated on the lower substrate 120. However, the present invention is not limited to the above-mentioned exemplary embodiment, but heat radiation may be generated on the lower substrate 120 and heat adsorption may be generated on the upper substrate 110.

In more detail, the top surface of the thermoelectric device 140 may contact the bottom surface of the first electrode layer 116 and the bottom surface of the thermoelectric device 140 may contact the top surface of the second electrode layer 126.

The thermoelectric device 140 may be configured to include a P-type thermoelectric device (P) and an N-type thermoelectric device (N).

In this case, the thermoelectric device 140 may be made of any one of, for example, bismuth (Bi), tellurium (Te), selenium (Se), and antimony (Sb) or at least one combination material.

As such, the thermoelectric module 100 according to the exemplary embodiment of the present invention forms the heat radiation layers 112 and 122 and the insulating layers 114 and 124 on the upper and lower substrates 110 and 120 in the square wave, such that the total surface areas of each of the heat radiation layers 112 and 122 and the insulating layers 114 and 124 may be increased about 2.5 times higher than those of the heat radiation layers 112 and 122 and the insulating layers 114 and 124 formed in the line shape.

Therefore, the surface areas of each of the upper and lower substrates 110 and 120 of the thermoelectric module 100 may be formed 5 times or higher than a sum of the surface areas of the heat radiation layers 112 and 122 and the insulating layers 114 and 124. Thereby, the thermoelectric module 100 may increase the thermal diffusion coefficient 5 times or higher than that of the related art, thereby increasing the heat radiation performance.

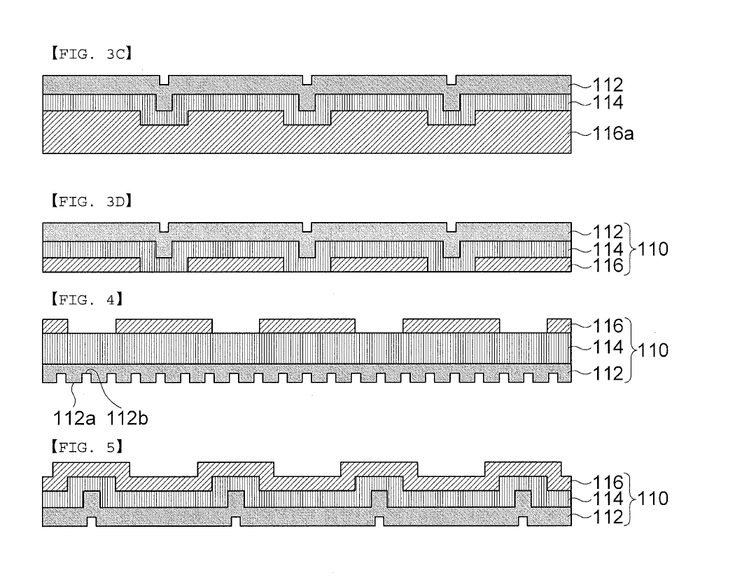

FIGS. 3A to 3D are cross-sectional views showing a method for manufacturing the upper substrate of FIG. 2.

First, as shown in FIG. 3A, a first pre-electrode layer 116a having a rugged form is formed.

In more detail, the first pre-electrode layer 116a of which the top surface has a rugged form may be formed by a dry or wet etching process after depositing metal materials.

In this case, a distance A between rugged portions formed on the top surface of the first pre-electrode layer 116a may be, for example, 5 to 100 μm and a height B of each of the rugged parts may be, for example, 2 to 10 μm.

In this case, the metal material may be any one of, for example, copper (Cu), aluminum (Al), silver (Ag), or the like, that are a conductive metal.

As shown in FIG. 3B, the first insulating layer 114 having the square wave pattern is formed along the surface of the first pre-electrode layer 116a.

In more detail, the first insulating layer 114 may be conformally formed by depositing polymer insulating materials over the entire surface of the first pre-electrode layer 116a.

In this case, the polymer insulating materials may be made of any one of, for example, alumina, boron nitride, aluminum nitride, silica, and polyimide that are an insulating material having high insulation and heat radiation property.

Further, as shown in FIG. 3C, the first heat radiation layer 112 may be formed by conformally depositing the metal materials along the surface of the first insulating layer 114.

In this case, the metal material may be any one of, for example, copper (Cu), aluminum (Al), silver (Ag), or the like, that are a conductive metal.

Thereafter, as shown in FIG. 3d, the first electrode layer 116 is formed to be buried into the groove of the first insulating layer 114 by removing the bottom surface of the first pre-electrode layer 116a by the etching process, thereby completing the upper substrate 110.

In this case, the etching process may be, for example, a lapping or polishing process.

As such, the thermoelectric module 100 according to the exemplary embodiment of the present invention forms the heat radiation layers 112 and 122 and the insulating layers 114 and 124 on the upper and lower substrates 110 and 120 in the square wave, such that the total surface areas of each of the heat radiation layers 112 and 122 and the insulating layers 114 and 124 may be increased about 2.5 times higher than those of the heat radiation layers 112 and 122 and the insulating layers 114 and 124 formed in the line shape.

Therefore, the surface areas of each of the upper and lower substrates 110 and 120 of the thermoelectric module 100 may be formed 5 times or higher than a sum of the surface areas of the heat radiation layers 112 and 122 and the insulating layers 114 and 124. Thereby, the thermoelectric module may increase the thermal diffusion coefficient 5 times or higher that of the related art, thereby increasing the heat radiation performance.

FIG. 4 is a cross-sectional diagram showing an upper substrate according to a second exemplary embodiment of the present invention.

As shown in FIG. 4, the upper substrate 110 according to the second exemplary embodiment of the present invention includes the first heat radiation layer 112, the first insulating layer 114, and the first electrode layer 116.

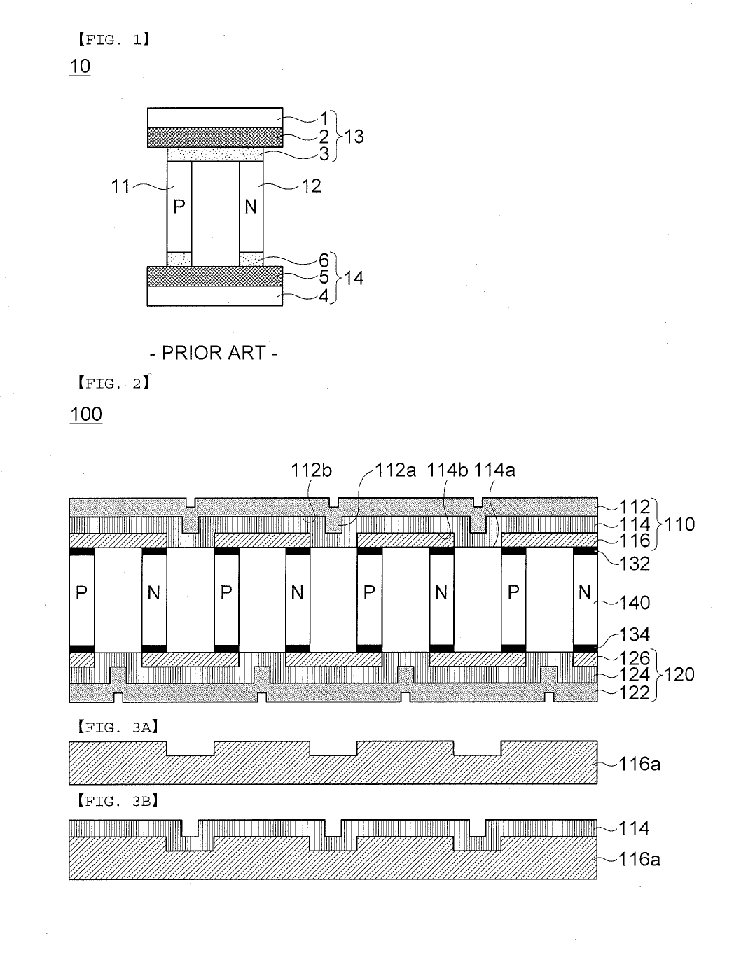

The first heat radiation layer 112 may perform the heat generation reaction or the heat adsorption reaction when power is applied to the thermoelectric module 100 of FIG. 1.

One surface of the first heat radiation layer 112 may be formed in the square pattern having the protrusion part 112a and the groove part 112b and the other surface of the first heat radiation layer 112, which is a surface contacting the first insulating layer 114 to be described below, may be formed in the line shape.

In the exemplary embodiment of the present invention, the case of forming one surface of the first heat radiation layer 112 in the square wave pattern increases a total surface area 1.5 times or higher than the case of forming both surfaces of the first heat radiation layer in the line shape to increase the thermal diffusion coefficient, thereby increasing the thermal diffusion rate.

In this configuration, the first heat radiation layer 112 may be made of any one of, for example, copper (Cu), aluminum (Al), silver (Ag), or the like, that are a conductive metal.

The first insulating layer 114, which is disposed between the first heat radiation layer 112 and the first electrode layer 116, may be used as an insulator so as not to cause an electrical short between the first heat radiation layer 112 and the first electrode layer 116 while serving to radiate heat.

The first insulating layer 114 is disposed along the other surface of the first heat radiation layer 112, such that the first insulating layer 114 may be formed in the line shape.

In this case, the first insulating layer 114 may be made of any one of, for example, alumina, boron nitride, aluminum nitride, silica, and polyimide that are an insulating material having high insulation and heat radiation property.

The first electrode layer 116, which is electrically connected to the thermoelectric device 140 of FIG. 1, may guide a flow of power when power is applied to the thermoelectric module 100.

As described above, the first electrode layer 116 may be formed in plural and may be formed on the other surface of the first insulating layer 114 at a predetermined interval.

In this case, the first electrode layer 116 may made of metal that is any one of, for example, copper (Cu), aluminum (Al), silver (Ag), or the like, that are a conductive metal having high electric conductivity.

Meanwhile, the second exemplary embodiment of the present invention describes only the upper substrate 110 of the upper and lower substrates 110 and 120, but the lower substrate 120 is formed in the same configuration and form as the upper substrate 110. As a result, the description thereof overlaps each other and will be omitted.

As such, the thermoelectric module 100 according to the exemplary embodiment of the present invention forms the heat radiation layers 112 and 122 and the insulating layers 114 and 124 on the upper and lower substrates 110 and 120 in the square wave, such that the total surface areas of each of the heat radiation layers 112 and 122 and the insulating layers 114 and 124 may be increased about 2.5 times higher than those of the heat radiation layers 112 and 122 and the insulating layers 114 and 124 formed in the line shape.

Therefore, the surface areas of each of the upper and lower substrate 110 and 120 of the thermoelectric module 100 may be formed 5 times or higher than a sum of the surface areas of the heat radiation layers 112 and 122 and the insulating layers 114 and 124. Thereby, the thermoelectric module 100 may increase the thermal diffusion coefficient 5 times or higher that of the related art, thereby increasing the heat radiation performance.

FIG. 5 is a cross-sectional diagram showing an upper substrate according to a third exemplary embodiment of the present invention.

As shown in FIG. 5, the upper substrate 110 according to the third exemplary embodiment of the present invention includes the first heat radiation layer 112, the first insulating layer 114, and the first electrode layer 116.

The first heat radiation layer 112 may perform the heat generation reaction or the heat adsorption reaction when power is applied to the thermoelectric module 100.

The first heat radiation layer 112 may be formed in the square wave pattern. In this case, the forming of the first heat radiation layer 112 of the exemplary embodiment of the present invention in the square wave pattern increases the total surface area 2.5 times or higher than forming both surfaces of the first heat radiation layer in the line shape so as to increase the thermal diffusion coefficient, thereby increasing the thermal diffusion rate.

In this configuration, the first heat radiation layer 112 may be made of any one of, for example, copper (Cu), aluminum (Al), silver (Ag), or the like, that are a conductive metal.

The first insulating layer 114, which is disposed between the first heat radiation layer 112 and the first electrode layer 116, may be used as an insulator so as not to cause an electrical short between the first heat radiation layer 112 and the first electrode layer 116 while serving to radiate heat.

As such, the first insulating layer 114 is disposed along the other surface of the first heat radiation layer 112, such that the first insulating layer 114 may be formed in the square wave pattern, similar to the first heat radiation layer 112. Thereby, the surface area of the first insulating layer 114 is increased 2.5 times or higher than that of the first insulating layer 114 of which both surfaces are formed in the line shape so as to increase the thermal diffusion coefficient, thereby increasing the thermal diffusion rate.

In this case, the first insulating layer 114 may be made of any one of, for example, alumina, boron nitride, aluminum nitride, silica, and polyimide that are an insulating material having high insulation and heat radiation property.

The first electrode layer 116, which is electrically connected to the thermoelectric device 140 of FIG. 1, may guide a flow of power when power is applied to the thermoelectric module 100.

As such, the first electrode layer 116 is disposed along the other surface of the first insulating layer 114, such that the first electrode layer 116 may be formed in the square wave pattern, similar to the first insulating layer 114. Thereby, the surface area of the first electrode layer 116 is increased, for example, 2.5 times or higher than that of the first electrode layer 116 formed in the line shape so as to increase the thermal diffusion coefficient, thereby increasing the thermal diffusion rate.

In this case, the first electrode layer 116 may be made of any one of, for example, copper (Cu), aluminum (Al), and silver (Ag) that are a conductive metal having high electric conductivity.

Meanwhile, the second exemplary embodiment of the present invention describes only the upper substrate 110 of the upper and lower substrates 110 and 120, but the lower substrate 120 is formed in the same configuration and form as the upper substrate 110. As a result, the description thereof overlaps each other and will be omitted.

As such, the thermoelectric module 100 forms the shapes of each of the heat radiation layers 112 and 122, the insulating layers 114 and 124, and the electrode layers 116 and 126 on the substrates 110 and 120 in the square wave pattern so as to increase the total thermal diffusion coefficient 7.5 times or higher, thereby increasing the thermal diffusion rate.

The exemplary embodiments of the present invention relate to the thermoelectric module. The thermoelectric module according to the exemplary embodiments of the present invention can form the heat radiation layer and the insulating layer on the upper and lower substrates as the square wave, thereby increasing the total surface areas of each of the heat radiation layer and the insulating layer about 2.5 times higher than those of the heat radiation layer and the insulating layer formed in the line shape.

Therefore, the surface areas of each of the upper and lower substrates of the thermoelectric module may be formed 5 times or higher than a sum of the surface areas of the heat radiation layer and the insulating layer.

Thereby, the thermoelectric module according to the exemplary embodiments of the present invention can increase the thermal diffusion coefficient 5 times or higher than that of the related art, thereby increasing the heat radiation performance.

While the present invention has been shown and described in connection with the embodiments, it will be apparent to those skilled in the art that modifications and variations can be made without departing from the spirit and scope of the invention as defined by the appended claims.

What is claimed is:

1. A thermoelectric module including a first substrate, a second substrate, a diffusion prevention layer, and a thermoelectric device, wherein each of the first and second substrates is stacked with:
a heat radiation layer performing heat generation reaction or heat adsorption reaction when power is applied to the thermoelectric module;
an insulating layer formed on one surface of the heat radiation layer and formed in a first square wave pattern having a first protrusion part and a first groove part; and
an electrode layer buried into the first groove part formed on a surface of the insulating layer.

2. The thermoelectric module according to claim 1, wherein the heat radiation layer is formed in a second square wave pattern having a second protrusion part and a second groove part.

3. The thermoelectric module according to claim 2, wherein the first square wave pattern is formed so as to surround one surface of the second square wave pattern.

4. The thermoelectric module according to claim 1, wherein the heat radiation layer is made of any one of copper (Cu), aluminum (Al), and silver (Ag) that are a conductive material.

5. The thermoelectric module according to claim 1, wherein the insulating layer is disposed between the heat radiation layer and the electrode layer to prevent an electrical short between the heat radiation layer and the electrode layer.

6. The thermoelectric module according to claim 1, wherein the insulating layer is made of any one of alumina, boron nitride, aluminum nitride, silica, and polyimide that are an insulating material having high insulation and heat radiation property.

7. The thermoelectric module according to claim 1, wherein the electrode layer is made of any one of copper (Cu), aluminum (Al), and silver (Ag) that are a conductive metal material having high electric conductivity.

8. A thermoelectric module including a first substrate, a second substrate, a diffusion prevention layer, and a thermoelectric device, wherein each of the first and second substrates is stacked with:
a heat radiation layer performing heat generation reaction or heat adsorption reaction when power is applied to the thermoelectric module and having both surfaces of a long side thereof formed in different patterns;
an insulating layer formed on one of both surfaces of the heat radiation layer and formed in a first square wave pattern having a first protrusion part and a first groove part; and
an electrode layer buried into the first groove part formed on a surface of the insulating layer.

9. The thermoelectric module according to claim 8, wherein the one surface of the heat radiation layer is formed in a second square wave pattern having a second protrusion part and a second groove part.

10. The thermoelectric module according to claim 9, wherein the other surface of both surfaces of the heat radiation layer is formed in a line shape.

11. The thermoelectric module according to claim 8, wherein the heat radiation layer is made of any one of copper (Cu), aluminum (Al), and silver (Ag) that is a conductive metal material.

12. The thermoelectric module according to claim 8, wherein the insulating layer is disposed between the heat radiation layer and the electrode layer to prevent an electrical short between the heat radiation layer and the electrode layer.

13. The thermoelectric module according to claim 8, wherein the insulating layer is made of any one of alumina, boron nitride, aluminum nitride, silica, and polyimide that are an insulating material having high insulation and heat radiation property.

14. A thermoelectric module including a first substrate, a second substrate, a diffusion prevention layer, and a thermoelectric device, wherein each of the first substrate and the second substrate is stacked with:
a heat radiation layer performing heat generation reaction or heat adsorption reaction when power is applied to the thermocouple module and formed in a first square wave pattern; and
an insulating layer formed along a top surface of the heat radiation layer and formed in a second square wave pattern; and an electrode layer formed along a top surface of the insulating layer and formed in a third square wave pattern.

15. The thermoelectric module according to claim 14, wherein the heat radiation layer is made of any one of copper (Cu), aluminum (Al), and silver (Ag) that are a conductive metal material.

16. The thermoelectric module according to claim 14, wherein the insulating layer is made of any one of alumina, boron nitride, aluminum nitride, silica, and polyimide that are an insulating material having high insulation and heat radiation property.

17. The thermoelectric module according to claim 14, wherein the electrode layer is made of copper (Cu), aluminum (Al), and silver (Ag) that is a conductive metal material having high electric conductivity.
